(19) United States
(12) Patent Application Publication
(10) Pub. No.: US 2009/0009365 A1
(43) Pub. Date: Jan. 8, 2009

(54) Track-detecting device and electronic device using the same

(75) Inventor: Chi-Cheng Lin, Taoyuan (TW)

Correspondence Address: BACON & THOMAS, PLLC, 625 SLATERS LANE, FOURTH FLOOR, ALEXANDRIA, VA, 22314-1176, US

(73) Assignee: BenQ Corporation, TAIPEI (TW)

(21) Appl. No.: 12/213,814

(22) Filed: Jun. 25, 2008

(30) Foreign Application Priority Data
Jul. 3, 2007 (TW) 96124222

(51) Int. Cl. H03M 11/00

(52) U.S. Cl. 341/20; 345/167

(57) ABSTRACT

The track-detecting device includes a track ball and a detection module. The track ball includes a plurality of first magnetic parts and a plurality of second magnetic parts. The magnetism of the first magnetic parts is opposite to that of the second magnetic parts. The detection module is adjacent to the track ball for detecting the variations of the magnetic forces in two directions. The variations of the magnetic forces are transformed to electric signals then output for determining the moving directions and the displacement of the track ball.

This application claims the benefit of Taiwan application Serial No. 96124222, filed Jul. 3, 2007, the subject matter of which is incorporated herein by reference.

### BACKGROUND OF THE INVENTION

1. Field of the Invention

The invention relates in general to a track-detecting device and an electronic device using the same, and more particularly to a track-detecting device detecting the track according to variation of magnetic force and an electronic device using the same.

2. Description of the Related Art

Nowadays, electronic devices with track balls detect the track mostly by using the following methods.

Please refer to FIG. 1. FIG. 1 illustrates a conventional photo-interruption track-detecting device. As shown in FIG. 1, the photo-interruption track-detecting device 100 includes a track ball 110, two photo interrupters 120 and 130, two axles 140 and 150 and two encoding units 180 and 190. The track ball 110 leans against the sleeves 140A and 150A of the axles 140 and 150. When the track ball 110 rotates, the axles 140 and 150 are driven to rotate as well. The encoding units 180 and 190 fixed on the axles 140 and 150 also rotate along with the axles 140 and 150. The encoding units 180 and 190 have, for example, several blades to interrupt the light from the photo interrupters 120 and 130. As a result, when the track ball 110 moves, the photo interrupters 120 and 130 adjacent to the encoding units 180 and 190 can easily determine the displacement and the moving directions of the track ball 110 by the emitting and receiving of optical signals.

Please refer to FIG. 2. FIG. 2 illustrates a conventional image sensing track-detecting device. As shown in FIG. 2, the image sensing track-detecting device 200 includes a track ball 210, a light-emitting diode 220, a circuit board 230 and an image sensor 240. The sphere of the track ball 210 usually has some specific patterns. The detecting method is to emit light from the light emitting diode 220 and project light onto the sphere of the track ball 210. The image reflected from the sphere is then detected by the image sensor 240, and the signal of the displacement is output to the circuit board 230. As a result, the displacement and the moving directions of the track ball 210 are calculated.

However, the electronic devices nowadays have to be in small size so that a user can easily carry the devices around. The track-detecting device in FIG. 1 can neither be simplified nor miniaturized to meet the requirement stated above due to the complexity of the mechanisms. As for the image sensing track-detecting device in FIG. 2, its cost is high, and the circuit design used is very complicated. This kind of track-detecting device has high cost and low market value.

### SUMMARY OF THE INVENTION

The invention is directed to a track-detecting device and an electronic device using the same. A track ball having uniform or non-uniform magnetized regions is used. A sensor detects the variation of magnetic forces of the track ball when the track ball is moving, so as to determine the displacement and moving directions of the track ball.

According to the present invention, a track-detecting device used in an electronic device is provided. The track-detecting device includes a track ball and a detection module. The track ball includes several first magnetic parts and second magnetic parts. The magnetism of the first magnetic parts is opposite to that of the second magnetic parts. The detection module is adjacent to the track ball for detecting the variations of the magnetic forces of the track ball in two directions. The detection module transforms the variations of the magnetic forces to electric signals and then output the electric signals to the electronic device. Accordingly, the electronic device determines the moving directions and the displacement of the track ball.

According to the present invention, an electronic device including a main body and a track-detecting device is provided. The main body includes a control unit. The track-detecting device is disposed on the main body and includes a track ball and a detection module. The track ball partially protrudes from the main body and includes several first magnetic parts and second magnetic parts. The magnetism of the first magnetic parts is opposite to that of the second magnetic parts. The detection module is adjacent to the track ball and electrically connected to the control unit. The detection module is used for detecting the variations of magnetic forces of the track ball in two directions. The detection module transforms the variations of the magnetic forces into electric signals and then output the electric signals to the control unit. Accordingly, the moving directions and the displacement of the track ball are determined.

The invention will become apparent from the following detailed description of the preferred but non-limiting embodiments. The following description is made with reference to the accompanying drawings.

### BRIEF DESCRIPTION OF THE DRAWINGS

FIG. 1 illustrates a conventional photo-interruption track-detecting device;

FIG. 2 illustrates a conventional image sensing track-detecting device;

FIG. 3A illustrates an electronic device according to a preferred embodiment of the present invention;

FIG. 3B illustrates a track-detecting device in FIG. 3A; and

FIG. 4 illustrates a circuit block diagram of the electronic device in FIG. 3A.

### DETAILED DESCRIPTION OF THE INVENTION

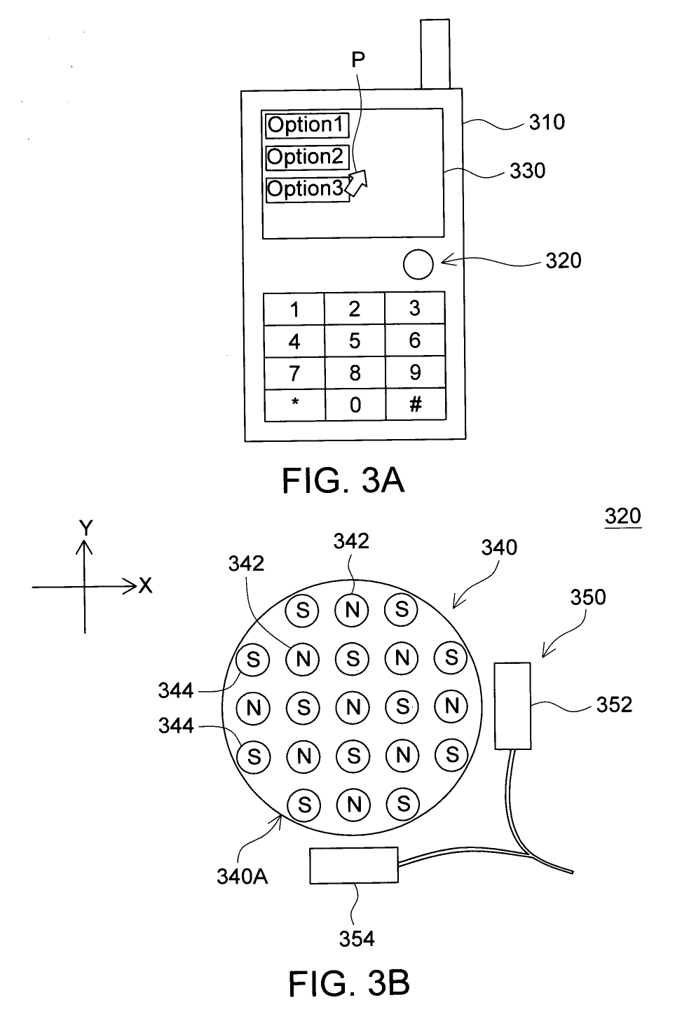

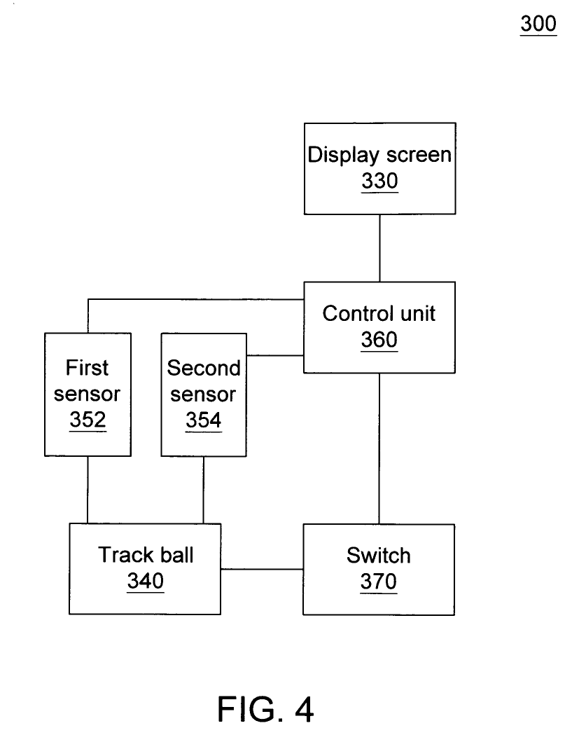

Please refer to FIGS. 3A, 3B and 4. FIG. 3A illustrates an electronic device according to a preferred embodiment of the present invention. FIG. 3B illustrates a track-detecting device in FIG. 3A. FIG. 4 illustrates a circuit block diagram of the electronic device in FIG. 3A. As shown in FIGS. 3A˜3B, the electronic device 300 includes a main body 310 and a track-detecting device 320. The track-detecting device 320 is disposed on the main body 310. A display screen 330 is disposed on the main body 310 of the electronic device 300. The location of a cursor P on the display screen 330 is changed when operating the track-detecting device 320.

The track-detecting device 320 includes a track ball 340 and a detection module 350. The track ball 340 partially protrudes from the main body 310 and is able to rotate relatively to the main body 310. The detection module 350 is adjacent to the track ball 340. The track ball 340 includes several first magnetic parts 342 and second magnetic parts 344. The magnetism of the first magnetic parts 342 is opposite to that of the second magnetic parts 344. For example, the magnetism of the first magnetic parts 342 is N pole, and the magnetism of the second magnetic parts 344 is S pole. Preferably, the first magnetic parts 342 and the second magnetic parts 344 are staggered on the sphere 340A of the track ball 340. Therefore, when the track ball 340 rotates, the magnetic field generated by the first magnetic parts 342 and the second magnetic parts 344 is changed accordingly.

In practice, uniform or non-uniform magnetized regions (that is, the first magnetic parts 342 and the second magnetic parts 344) are formed by magnetizing the surface of the track ball 340. When the magnetized regions are arranged more evenly on the track ball 340, the detection module 350 is more sensitive to the variations of the magnetic forces on the surface of the track ball 340.

As to the detection module 350, it is adjacent to the track ball 340 and electrically connected with a control unit 360 (shown in FIG. 4) in the main body 310. When the track ball 340 moves or rotates, the detection module 350 detects the variations of magnetic forces of the track ball 340 in two directions. The detection module 350 transforms the variations of the magnetic forces to electric signals and then output the electric signals to the control unit 360. Accordingly, the moving directions and the displacement of the track ball 340 are determined.

In order to detect the variations of the magnetic forces of the track ball 340 in two directions, the detection module 350 includes a first sensor 352 and a second sensor 354 which are able to detect the variation of magnetic forces. The first sensor 352 and the second sensor 354 are adjacent to the track ball 340 respectively. When the track ball 340 rotates, the first sensor 352 is able to detect the variation of magnetic force in a first direction, and the second sensor 354 is able to detect the variation of magnetic force in a second direction. Preferably, the first direction is perpendicular to the second direction. For example, the first direction is the x-direction in FIG. 3B, and the second direction is the y-direction or z-direction in FIG. 3B (the second direction is y-direction in the present embodiment as an example).

The first sensor 352 and the second sensor 354 are preferably Hall sensors. Hall sensor outputs voltage at different level based on the variation of the detected magnetic force. The first magnetic parts 342 and the second magnetic parts 344 are distributed evenly on the track ball 340, and the magnetism of the first magnetic parts 342 is opposite to that of the second magnetic parts 344. When the track ball 340 rotates, the first magnetic parts 342 and the second magnetic parts 344 are driven to move, so that the magnetic field changes continuously, which results in variations of magnetic forces. When the first magnetic parts 342 and the second magnetic parts 344 repeatedly pass by the Hall sensors, the variations of magnetic forces of the track ball 340 in x-direction and y-direction are detected by the Hall sensors. The Hall sensors transform the variations of magnetic forces to electric signals and then output the electric signals to the control unit 360.

When the user controls the movement of the track ball 340 to place the cursor P over the desired item such as the option 1, 2 or 3 in FIG. 3A, the item can be selected directly through the track ball 340. As shown in FIG. 4, the electronic device 300 further includes a switch 370. The switch 370 is electrically connected to the control unit 360. Preferably, the switch 370 is adjacent to the track ball 360, so that the track ball 340 is able to actuate the switch 370. For example, the switch 370 is disposed between the track ball 340 and the main body 310 (shown in FIG. 3A), and the track ball 340 is floating (for example, the track ball 340 is supported by a spring) over the switch 370. Therefore, after the user moves the cursor P to the desired item (such as the option 1, 2 or 3 in FIG. 3A), the user can press the track ball 340 directly. The track ball 340 then moves downward to actuate the switch 370. When the switch 370 is actuated, an electric signal is generated from the switch 370 and then sent to the control unit 360 to inform the control unit 360 that the user has chosen a specific item.

The electronic device 300 with a track-detecting device 320 according to the present invention is, for example, a mobile phone, a smart phone, a personal digital assistant (PDA), or a global positioning system (GPS) device. A user therefore can select, change, add or delete an item on the display screen 330 by directly rotating the track ball 340 on the electronic device 300.

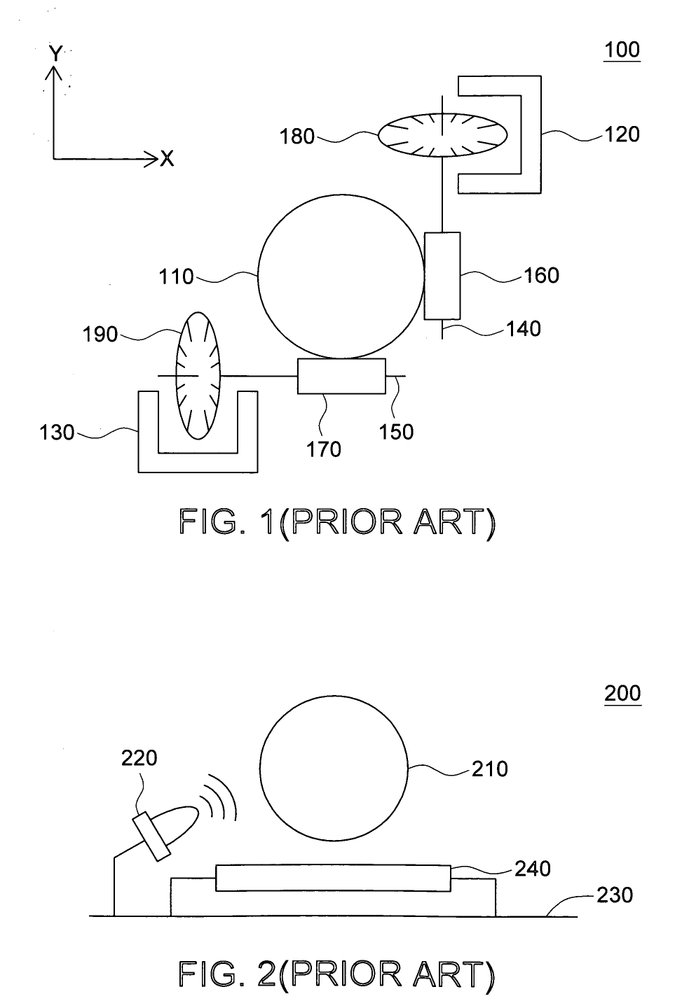

Compared to the conventional track-detecting devices 100 and 200 (shown in FIGS. 1 and 2) using a photo interrupter or an image sensor, the track-detecting device 320 of the present embodiment uses a track ball 340 with magnetized regions and a detection module 350. The structure is simpler than that of the conventional devices, and the cost is lower as well. In addition, the volume of the track-detecting device is minimized because of the small volume of the sensors. Therefore, any kind of electronic device using the track-detecting device of the present embodiment has the advantages of light weight and low cost.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A track-detecting device used in an electronic device, the track-detecting device comprising:
a track ball comprising a plurality of first magnetic parts and second magnetic parts, the magnetism of the first magnetic parts being opposite to that of the second magnetic parts; and
a detection module adjacent to the track ball, for detecting the variation of magnetic forces of the track ball in two directions, the detection module transforming the variations of magnetic forces to electric signals and then outputting the electric signals to the electronic device, the electronic device determining the moving direction and the displacement of the track ball accordingly.

2. The track-detecting device according to claim 1, wherein the detection module comprises a first sensor and a second sensor, each adjacent to the track ball.

3. The track-detecting device according to claim 2, wherein the first sensor and the second sensor are two Hall sensors.

4. The track-detecting device according to claim 2, wherein the first sensor detects the variation of magnetic force of the track ball in a first direction, and the second sensor detects the variation of magnetic force of the track ball in a second direction when the track ball rotates.

5. The track-detecting device according to claim 4, wherein the first direction is substantially perpendicular to the second direction.

6. The track-detecting device according to claim 1, wherein the first magnetic parts and the second magnetic parts are located on the sphere of the track ball.

7. The track-detecting device according to claim 1, wherein the first magnetic parts and the second magnetic parts are staggered.

8. The track-detecting device according to claim 1, wherein the electronic device includes a control unit electrically connected to the detection module for receiving the electric signals.

9. An electronic device comprising:
a main body comprising a control unit; and
a track-detecting device disposed on the main body and comprising:
a track ball partially protruding from the main body and comprising a plurality of first magnetic parts and second magnetic parts, the magnetism of the first magnetic parts being opposite to that of the second magnetic parts; and
a detection module adjacent to the track ball and electrically connected to the control unit, for detecting the variations of magnetic forces of the moving track ball in two directions, the detection module transforming the variations of the magnetic forces to electric signals and then outputting the electric signals to the control unit, for determining the moving directions and the displacement of the track ball.

10. The electronic device according to claim 9, wherein the detection module comprises a first sensor and a second sensor, each adjacent to the track ball.

11. The electronic device according to claim 10, wherein the first sensor and the second sensor are two Hall sensors.

12. The electronic device according to claim 10, wherein the first sensor detects the variation of magnetic force of the track ball in a first direction, and the second sensor detects the variation of magnetic force of the track ball in a second direction when the track ball rotates.

13. The electronic device according to claim 12, wherein the first direction is substantially perpendicular to the second direction.

14. The electronic device according to claim 9, wherein the first magnetic parts and the second magnetic parts are located on the sphere of the track ball.

15. The electronic device according to claim 9, wherein the first magnetic parts and the second magnetic parts are staggered.

16. The electronic device according to claim 9 further comprising:
a switch electrically connected to the control unit and adjacent to the track ball, wherein the switch is actuated by the track ball.

17. The electronic device according to claim 16, wherein the track ball is spring-loaded on the main body, and the switch is actuated via the pressing of the track ball, so as to generate a signal that is sent to the control unit.
